(19) United States
(12) Patent Application Publication
(10) Pub. No.: US 2022/0033955 A1
(43) Pub. Date: Feb. 3, 2022

(54) METHOD FOR PRODUCING THIN FILM AND MULTILAYER BODY

(71) Applicant: Panasonic Intellectual Property Management Co., Ltd., Osaka (JP)

(72) Inventors: MANABU KANOU, Osaka (JP); YUJI ZENITANI, Nara (JP); YUKI NAKATA, Osaka (JP)

(21) Appl. No.: 17/505,099

(22) Filed: Oct. 19, 2021

Related U.S. Application Data
(63) Continuation of application No. PCT/JP2020/018055, filed on Apr. 28, 2020.

(30) Foreign Application Priority Data
Jul. 23, 2019 (JP) 2019-135555
Apr. 10, 2020 (JP) 2020-071247

(51) Int. Cl. C23C 14/08; H01J 37/34; C01G 23/00; C01B 6/02; C01B 6/24; C23C 14/34

(52) U.S. Cl. CPC C23C 14/088; H01J 37/3429; C01G 23/006; C01P 2002/34; C01B 6/24; C23C 14/34; C01B 6/02

(57) ABSTRACT

A method for producing a thin film according to the present disclosure comprises a step of forming the thin film on a substrate using a target. The target is formed of a mixture containing a first material and a second material. The first material has a composition represented by ATiO₃ (where A is at least one selected from the group consisting of Ba and Sr). The second material has a composition represented by EH₂ (where E is at least one selected from the group consisting of Ti and Zr). The thin film is formed of a first oxide containing A, Ti, and O. Some of oxide ions contained in the first oxide have been replaced by hydride ions.

### CROSS REFERENCE TO RELATED APPLICATIONS

This is a continuation application of International Application No. PCT/JP2020/018055, with an international filing date of Apr. 28, 2020, which claims priorities of Japanese Patent Application No.; 2019-135555 filed on Jul. 23, 2019, and Japanese Patent Application No.: 2020-071247 filed on Apr. 10, 2020, the contents of which are incorporated herein by reference.

### BACKGROUND

### 1. Technical Field

The present disclosure relates to a method for producing a thin film and a multilayer body.

### 2. Description of the Related Art

Japanese Unexamined Patent Application Publication No. 5-239635 (hereinafter, referred to as Patent Literature 1) discloses a method in which a transparent conductive film having a component contained in a target is formed on a substrate. The target contains a hydrogen compound. The hydrogen compound of Patent Literature 1 serves only as a supply source of protic hydrogen (H⁺) for the conductive film to be formed. Examples of the hydrogen compound include In(OH)₃ and H₂SnO₃.

Fadhel E I Kamel, “BaTiO3: H Films as All-Solid-State Electrolytes for Integrated Electric Double-Layer Capacitors”. In Zoran Stevic (Ed), “Supercapacitor Design and Applications”, 2016, Intech Open (hereinafter, referred to as Non-Patent Literature 1) discloses formation of a titanium-containing oxide film by sputtering in an argon atmosphere containing 0 to 30% hydrogen. The color tone of a BiTiO₃ film of Non-Patent Literature 1 is not blue which indicates the presence of hydride ions, but is yellow to dark brown. This is assumed to be caused by protic hydrogen incorporated during the film formation. Furthermore, the film of Non-Patent Literature 1 has an AC resistivity of greater than or equal to about 1 MΩ·cm. In other words, the film of Non-Patent Literature 1 has high resistance.

Japanese Patent No. 5872555 (hereinafter, referred to as Patent Literature 2) discloses a thin film of a perovskite-type, titanium-containing oxide containing hydride ions (H⁻). In Patent Literature 2, a thin film is formed as follows. First, a single-crystal MTiO₃ thin film is formed on an LSAT substrate. M represents Ba, Sr, or Ca. LSAT is an abbreviation of (LaAlO₃)_{0.3}(SrAl_{0.5}Ta_{0.5}O₃)_{0.7}. Next, the thin film, together with a CaH₂ powder which is a reducing agent as well as a hydride ion supply source, is vacuum sealed in a quartz tube, and heat treatment is performed at a temperature of 300° C. to 530° C. for one day.

Xin Liu et al., “Formation and migration of hydride ions in BaTiO₃₋ₓHₓoxyhydride”, Journal of Materials Chemistry A, 2017, 5, 1050-1056 (hereinafter, referred to as Non-Patent Literature 2) reveals that the presence of hydrogen as hydride ions most stabilizes BaTiO₃₋ₓHₓ. Furthermore, Non-Patent Literature 2 discloses that because of the presence of hydride ions, BaTiO₃₋ₓHₓ exhibits blue color, and describes that the reason for the blue coloration is due to polarons generated by binding of electrons in the titanium site.

### SUMMARY

One non-limiting and exemplary embodiment provides a novel technique for producing a thin film of a titanium-containing oxide containing hydride ions and a novel multilayer body which comprises the thin film and a substrate.

In one general aspect, the techniques disclosed here feature a method for producing a thin film. The method comprises a step of forming the thin film on a substrate using a target. The target is formed of a mixture containing a first material and a second material. The first material has a composition represented by ATiO₃ (where A is at least one selected from the group consisting of Ba and Sr), The second material has a composition represented by EH₂ (where E is at least one selected from the group consisting of Ti and Zr). The thin film is formed of a first oxide containing A, Ti, and O. Some of oxide ions contained in the first oxide have been replaced by hydride ions.

The present disclosure provides a novel technique for producing a thin film of a titanium-containing oxide containing hydride ions and a novel multilayer body which comprises the thin film and a substrate.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram showing a possible crystal structure of a first oxide constituting a thin film according to the present disclosure;

FIG. 2 is a flowchart for explaining an example of a method according to the present disclosure;

FIG. 3 is a sectional view schematically showing an example of a multilayer body according to the present disclosure;

FIG. 4 is a sectional view schematically showing another example of a multilayer body according to the present disclosure;

FIG. 5 is a graph showing an X-ray diffraction profile of a thin film of Example 1 (see the upper part thereof) and simulation data obtained from a crystal structure database (see the lower part thereof);

FIG. 6 is a graph showing an X-ray diffraction profile at the (011) plane of the thin film of Example 1 in the rotation angle direction (see the upper part thereof) and an X-ray diffraction profile at the (022) plane of an MgO substrate in the rotation angle direction (see the lower part thereof);

FIG. 7 is a graph showing the analysis results of Rutherford back scattering spectrometry/hydrogen forward scattering spectrometry (hereinafter, referred to as as “RBS/HFS”) on the thin film of Example 1;

FIG. 8 is a graph showing the analysis results of RBS/HFS on a substrate of Example 1 after a thin film has been formed thereon;

FIG. 9 is a graph showing the electrical conductivity of the thin film of Example 1;

FIG. 10 is a graph showing an X-ray diffraction profile of a thin film of Example 2 (see the upper part thereof) and simulation data obtained from a crystal structure database (see the lower part thereof);

FIG. 11 is a graph showing an X-ray diffraction profile of a thin film of Example 3 (see the upper part thereof), an X-ray diffraction profile of a thin film of Example 4 (see the middle part thereof), and simulation data obtained from a crystal structure database (see the lower part thereof);

FIG. 12 is a graph showing the electrical conductivity of a thin film of Example 4;

FIG. 13 is a graph showing an X-ray diffraction profile of a thin film of Example 5 (see the upper part thereof), an X-ray diffraction profile of a stainless steel substrate (see the middle part thereof), and simulation data obtained from a crystal structure database (see the lower part thereof);

FIG. 14 is a graph showing an X-ray diffraction profile of a thin film of Example 6 (see the upper part thereof) and simulation data obtained from a crystal structure database (see the lower part thereof);

FIG. 15 is a graph showing an X-ray diffraction profile of a thin film of Example 7 (see the upper part thereof) and simulation data obtained from a crystal structure database (see the lower part thereof);

FIG. 16 is a graph showing an X-ray diffraction profile of a thin fill of Comparative Example 1; and

FIG. 17 is a graph showing an X-ray diffraction profile of a thin film of Comparative Example 2 (see the upper part thereof) and simulation data obtained from a crystal structure database (see the lower part thereof).

### DETAILED DESCRIPTION

According to the method of the present disclosure, unlike the methods of Patent Literature 1 and Non-Patent Literature 1, a thin film of a titanium-containing oxide containing hydride ions (H⁻) can be produced. Consequently, it is possible to produce, for example, a thin film of a titanium-containing oxide having electron conductivity and hydride ion conductivity sufficient for use as a reaction electrode. Furthermore, according to the method of the present disclosure, unlike the method of Patent Literature 2, it is possible to omit heat treatment using a reducing agent after formation of a thin film on a substrate. In other words, in the method of the present disclosure, it is possible to produce a thin film of a titanium-containing oxide containing hydride ions, for example, in one film formation step. Therefore, according to the method of the present disclosure, a thin film of a titanium-containing oxide containing hydride ions can be produced efficiently.

### Embodiments of the Present Disclosure

The embodiments of the present disclosure will be described below with reference to the drawings.

### [Thin Film of Titanium-Containing Oxide Containing Hydride Ions]

A thin film produced by the method according to the present disclosure is formed of a first oxide containing elements A, Ti, and O, The element A is at least one selected from the group consisting of Ba and Sr. Some of oxide ions contained in the first oxide have been replaced by hydride ions. In other words, the first oxide contains hydride ions. The replacement amount of hydride ions with respect to oxide ions is, for example, greater than or equal to 1 atomic percent, and may be greater than or equal to 10 atomic percent, or greater than or equal to 20 atomic percent. The upper limit of the replacement amount is, for example, less than or equal to 33.3 atomic percent.

The first oxide usually has hydride ion conductivity.

The first oxide may have a crystal structure. In this case, the thin film is a crystalline film. The crystal structure is, for example, a perovskite structure.

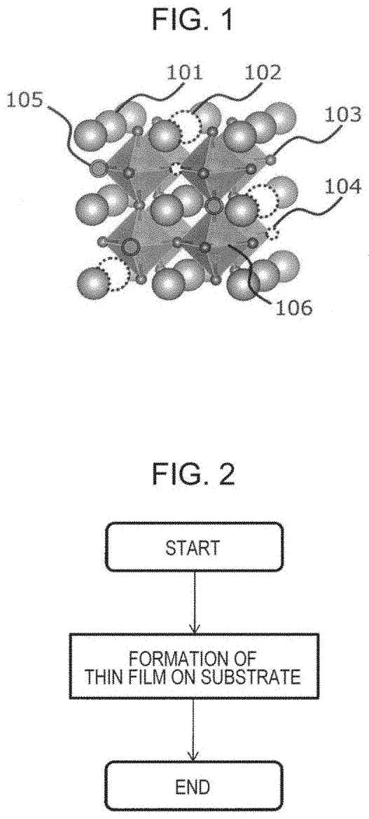

The first oxide may have a composition represented by AₓTiO_{3-y}H_{z} (0.4≤x≤0.8, 0.1≤y≤1.0, 0.1≤z≤1.0). The first oxide having this composition can have a perovskite structure. An example of the perovskite structure is shown in FIG. 1. Reference numeral 101 in FIG. 1 represents at least one ion selected from the group consisting of a Ba ion and an Sr ion. Reference numeral 102 represents a vacancy of at least one ion selected from the group consisting of a Ba ion and an Sr ion. Reference numeral 103 represents an oxide ion, Reference numeral 104 represents a vacancy of an oxide ion. Reference numeral 105 represents a hydride ion introduced by replacement into an oxide ion site. Reference numeral 106 represents a Ti ion.

Hereinafter, a first oxide consisting essentially of Ba, Ti, and O is referred to as “BTOH”. A first oxide consisting essentially of Sr, Ti, and O is referred to as “STOH”. BTOH may have a composition represented by BaₓTiO_{3-y}H_{z} (0.4≤x≤0.8, 0.1≤y≤1.0, 0.1≤z≤1). STOH may have a composition represented by SrₓTiO_{3-y}H_{z} (0.4≤x≤0.8, 0.1≤y≤1.0, 0.1≤z≤1).

The first oxide may contain Zr. In the case where Zr is contained, the content of Zr in the first oxide is, for example, less than or equal to 20 mol %, and may be less than or equal to 1 mol %. Zr is typically derived from a target that can be used in the method according to the present disclosure.

The first oxide can contain other elements as impurities, for example, with a content of less than or equal to 1 mol %. The content of impurities may be less than or equal to 0.1 mol %.

The thin film can contain a material other than the first oxide, for example, with a content of less than or equal to 1% by weight. The content of the material may be less than or equal to 0.1% by weight.

The thin film can be utilized, for example, for a material for chemical conversion, a catalyst, or an electrode, each of which adds hydrogen to organic substance. Examples of the electrode include a reaction electrode. However, the use of the thin film is not limited to the examples described above.

The thickness of the thin film is, for example, greater than or equal to 1 nm and less than or equal to 1,000 nm, and may be greater than or equal to 10 nm and less than or equal to 350 nm.

### [Method for Producing Thin Film]

### (Substrate)

A substrate is, for example, formed of at least one selected from the group consisting of Si, Ge, a metal, an amorphous substance, and a metal compound that is different from the first oxide. The substrate may be formed of at least one selected from the group consisting of Si and Ge. The metal compound may be a second oxide that is different from the first oxide. However, the material constituting the substrate is not limited to the examples described above.

The metal is, for example, stainless steel. The amorphous substance is, for example, glass. However, the metal and the amorphous substance are not limited to the examples described above.

The metal compound may be at least one selected from the group consisting of Al₂O₃, SnO, GaAs, GaN, MgO, and BaSnO₃. However, the metal compound is not limited to the examples which have been described above and will be described later.

The metal compound may have a higher oxidation-reduction potential than a hydride ion. The oxidation-reduction potential is typically a standard oxidation-reduction potential. Note that it is difficult for the method of Patent Literature 2 to form the thin film using a substrate formed of at least one selected from the group consisting of Si, Ge, and a metal compound having a higher oxidation-reduction potential than a hydride ion. The reason for this is that the reducing agent composed of a hydride used in the method of Patent Literature 2 strongly erodes such a substrate. For example, H. Wu, et al., “Structural variations and hydrogen storage properties of Ca₅Si₃ with Cr₅B₃-type structure”, 2008, Chemical Physics Letters, vol. 460, Issues pp. 432-437 shows that Si is transformed into a hydride containing Ca and Si by reaction with CaH₂ having high reducing power. The method according to the present disclosure is also advantageous in that the thin film can be produced using a substrate formed of at least one selected from the group consisting of Si, Ge, and the metal compound. From this viewpoint, the substrate may be formed of at least one selected from the group consisting of Si, Ge, and a metal compound having a higher oxidation-reduction potential than a hydride ion. Furthermore, the fact that a thin film can be formed on a substrate formed of at least one selected from the group consisting of Si and Ge is a large advantage for the application of the thin film to a semiconductor device. Among the materials described above, at least one selected from the group consisting of Al₂O₃, SnO, GaAs, and GaN corresponds to the metal compound.

The metal compound may be a substance which has been doped with hydrogen by heat treatment using a reducing agent composed of a hydride. The heat treatment may be, for example, the heat treatment disclosed in Patent Literature 2. Being doped with hydrogen typically means being transformed into a hydride. In the case where a substrate formed of such a material is used, it is difficult to form a thin film through the heat treatment. The reason therefor is that even the substrate is transformed into a hydride, resulting in a change in properties, J. Matsumoto et al., “Superconductivity at 48 K of heavily hydrogen-doped SmFeAsO epitaxial films grown by topotactic chemical reaction using CaH₂” arXiv:1903.11819 shows that by carrying out the heat treatment on a thin film formed on an MgO substrate, about 1% by weight of hydrogen was incorporated into the substrate. Note that the thin film of J. Matsumoto does not contain the first oxide. The reducing agent used in J. Matsumoto is CaH₂. Furthermore, H. Wu, et al., “Structural variations and hydrogen storage properties of Ca₅Si₃ with Cr₅B₃— type structure”, 2008, Chemical Physics Letters, vol. 460, Issues 4-6, pp. 432-437 shows that Si is transformed into a hydride containing Ca and Si by reaction with CaH₂ having high reducing power. On the other hand, the method according to the present disclosure is also advantageous in that a thin film can be produced without changing the properties of a substrate that is likely to be transformed into a hydride. Among the materials described above, at least one selected from the group consisting of MgO and BaSnO₃ corresponds to the compound. Furthermore, Si and Ge are also substances which are doped with hydrogen by the heat treatment. From this viewpoint, the substrate may be formed of at least one selected from the group consisting of Si, Ge, and a metal compound which has been doped with hydrogen by heat treatment using a reducing agent composed of a hydride.

In the method according to the present disclosure, it is possible for example to set the hydrogen content in the substrate after formation of the thin film to be less than or equal to 0.05 mol %. The hydrogen content can be less than or equal to 0.04 mol %, less than or equal to 0.03 mol %, less than or equal to 0.02 mol %, or less than or equal to 0.015 mol %. The lower limit of the hydrogen content is, for example, greater than or equal to 0.001 mol %. In this case, the substrate may be formed of at least one selected from the group consisting of (i) a metal compound having a higher oxidation-reduction potential than a hydride ion, (ii) a metal compound which is doped with hydrogen by heat treatment using a reducing agent composed of a hydride, (iii) Si, and (iv) Ge. The hydrogen content in the substrate can be evaluated, for example, by RBS/HFS. In the present specification, the hydrogen content in the substrate means the ratio of hydrogen atoms to all atoms constituting the substrate, i.e., the amount of hydrogen determined by the ratio of constituent elements.

The substrate may have a crystal structure. The crystal structure may be a single crystal structure. Examples of the substrate having a crystal structure include an Si substrate having a (100) plane orientation, an MgO substrate having a (100) or (110) plane orientation, and an Al₂O₃ substrate having a (001) plane orientation. However, the substrate having a crystal structure is not limited to the examples described above.

A thin film may be epitaxially grown on a substrate having a crystal structure, e.g., an MgO substrate having a (100) plane orientation.

### (Target)

A target is formed of a mixture containing a first material and a second material. The first material has a composition represented by ATiO₃ (where A is at least one selected from the group consisting of Ba and Sr). The first material may have a composition represented by BaTiO₃ or a composition represented by SrTiO₃. The second material has a composition represented by EH₂ (where E is at least one selected from the group consisting of Ti and Zr). The second material may have a composition represented by TiH₂ or a composition represented by ZrH₂, and may have a composition represented by TiH₂.

In the case where a thin film formed of BTOH (hereinafter, referred to as a “BTOH thin film”) is produced, the first material may have a composition represented by BaTiO₃, and a mixing ratio (X:Y) of the first material (X) and the second material (Y) in the mixture, in terms of molar ratio, may be in a range of 1:0.01 to 1:1. The mixing ratio (X:Y) in terms of molar ratio may be in a range of 1:0.1 to 1:0.5.

In the case where a thin film formed of STOH (hereinafter, referred to as a “STOH thin film”) is produced, the first material may have a composition represented by SrTiO₃, and a mixing ratio (X:Y) of the first material (X) and the second material (Y) in the mixture, in terms of molar ratio, may be in a range of 1:0.01 to 2:1. The mixing ratio (X:Y) in terms of molar ratio may be in a range of 1:0.1 to 1:1.

At least one selected from the group consisting of the first material and the second material may be a powder. In the present specification, the powder means particles each of which can pass through a sieve with an opening of 45 μm.

### (Film Formation Method)

A thin film of a titanium-containing oxide containing hydride ions can be formed on a substrate by film formation using the target described above. Examples of the film formation technique include sputtering and pulsed laser deposition (hereinafter, referred to as PLD). FIG. 2 shows an example of a method according to the present disclosure. As shown in FIG. 2, in the method according to the present disclosure, the thin film is formed on a substrate.

In order to form BaTiO₃ thin films, usually, a high temperature of about 600° C. is required. M. Matsuoka et al., “Low-temperature epitaxial growth of BaTiO₃ films by radio-frequency-mode electron cyclotron resonance sputtering”, Journal of Applied Physics, 76, 1768(1994) and T. L. Rose et al., “characterization of rf-sputtered BaTiO₃ thin films using a liquid electrolyte for the top contact”, Journal of Applied Physics, 55, 3706(1984) each disclose formation of BaTiO₃ thin films at a lower temperature. However, even in that case, a high temperature of about 350° C. is required. Furthermore, in order to obtain a BaTiO₃ thin film having a crystal structure, heat treatment for crystallization is required.

On the other hand, in the method according to the present disclosure, film formation at lower than 500° C. is possible. The film formation temperature may be normal temperature. Furthermore, by selecting an appropriate substrate, it is possible to form an amorphous thin film or to form a thin film having a crystal structure. A thin film having a crystal structure can be formed, for example, by epitaxial growth.

The film formation atmosphere may contain oxygen. The oxygen content in the film formation atmosphere is usually less than or equal to 20 mol %, The film formation atmosphere may not substantially contain oxygen. The expression “not substantially contain” means that the content is, for example, less than 0.005 mol %. The film formation atmosphere may be an inert atmosphere composed of at least one selected from the group consisting of nitrogen and an inert gas.

In the method according to the present disclosure, unlike the method of Patent Literature 2, it is possible to omit heat treatment using a reducing agent after formation of a thin film. Therefore, for example, a thin film having hydride ion conductivity can be more efficiently produced. Furthermore, it is possible to avoid damage generated due to the reducing agent. This improves, for example, a degree of freedom in selecting at least one from the group consisting of a material and a structure of a substrate. Examples of the substrate that can be selected include a structure body having a side surface thereof is exposed, such as a pellet. For example, it is also possible to entirely cover the surface of a pellet with a thin film,

### [Multilayer Body]

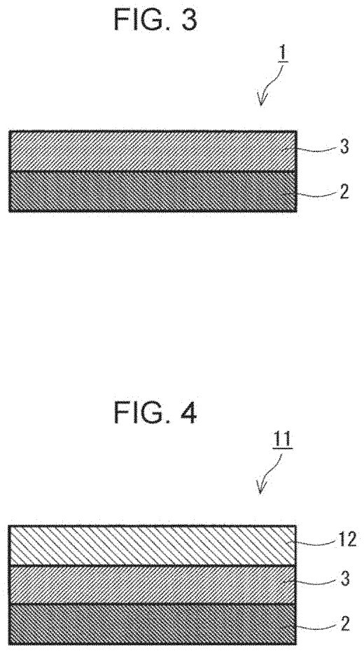

A thin film can be for example supplied, together with a substrate, as a multilayer body. FIG. 3 shows an example of a multilayer body. A multilayer body 1 shown in FIG. 3 comprises a substrate 2 and a thin film 3 formed on the substrate 2. The substrate 2 and the thin film 3 are as described above.

The multilayer body 1 comprising the substrate 2 which is formed of at least one selected from the group consisting of Si, Ge, a metal compound having a higher oxidation-reduction potential than a hydride ion, and a metal compound which has been doped with hydrogen by heat treatment using a reducing agent composed of a hydride is a novel multilayer body 1 that cannot be produced by existing methods.

That is, the multilayer body comprises:

a substrate; and

a thin film formed on the substrate,

wherein,

the thin film is formed of a first oxide containing A; Ti, and O,

where A is at least one selected from the group consisting of Ba and Sr,

some of oxide ions contained in the first oxide have been replaced by hydride ions,

the substrate is formed of at least one selected from the group consisting of Si, Ge, and a metal compound that is different from the first oxide, and

the metal compound is a substance

(a) which has a higher oxidation-reduction potential than a hydride ion, or

(b) which has been doped with hydrogen by heat treatment using a reducing agent composed of a hydride.

The substrate may be formed of at least one selected from the group consisting of Si and Ge.

The metal compound may be at least one selected from the group consisting of Al₂O₃, SnO, GaAs, GaN, MgO, and BaSnO₃.

Furthermore, the multilayer body 1 comprising the substrate 2 in which the hydrogen content is less than or equal to 0.05 mol % is a novel multilayer body 1 that failed to be produced by existing methods.

That is, the multilayer body comprises;

a substrate; and

a thin film formed on the substrate,

wherein,

the thin film is formed of a first oxide containing A, Ti, and O,

where A is at least one selected from the group consisting of Ba and Sr,

some of oxide ions contained in the first oxide have been replaced by hydride ions, and

a hydrogen content in the substrate is less than or equal to 0.05 mol %,

The hydrogen content in the substrate may be less than or equal to 0.04 mol %, less than or equal to 0.03 mol %, less than or equal to 0.02 mol %, or less than or equal to 0.015 mol %, The lower limit of the hydrogen content is, for example, greater than or equal to 0.001 mol %,

The substrate may be formed of at least one selected from the group consisting of Si and Ge,

The multilayer body according to the present disclosure may comprise an additional layer other than the substrate 2 and the thin film 3. FIG. 4 shows another example of a multilayer body. A multilayer body 11 shown in FIG. 4 comprises the substrate 2, the thin film 3 formed on the substrate 2, and an additional layer 12 formed on the thin film 3. The thin film 3 may be disposed between the additional layer 12 and the substrate 2, Examples of the additional layer 12 include an electrode layer and a conductive layer. The conductive layer is, for example, formed of a conductive material, such as gold (Au).

### EXAMPLES

The method and the multilayer body according to the present disclosure will be described in more detail below with reference to Examples. However, the method and the multilayer body according to the present disclosure are not limited to embodiments shown in the examples below.

### Example 1

### (Purchase of Substrate)

An MgO substrate having a (100) plane orientation was purchased from Crystal Base Co., Ltd.

### (Production of Target)

A BaTiO₃ powder (purchased from Kojundo Chemical Laboratory Co., Ltd., purity: 99.9%) and a TiH₂ powder (purchased from Kojundo Chemical Laboratory Co., Ltd., purity: 99%) were thoroughly mixed in the air to provide a mixed powder. The mixing ratio of the BaTiO₃ powder and the TiH₂ powder, in terms of molar ratio, was 10:3. A dish formed of Cu with a diameter of 100 mm was uniformly filled with the mixed powder to provide a target,

### (Formation of Thin Film)

Using the resulting target and an RF magnetron sputtering system (manufactured by Kenix, trade name: 4-inch RF sputtering system), a BTOH thin film was formed on the MgO substrate having a (100) plane orientation. The sputtering conditions were as follows:

Sputtering power: 240 W

Sputtering pressure: 1 Pa

Sputtering gas: Ar

Substrate temperature: lower than or equal to 420° C.

The resulting thin film had a thickness of 400 nm. The sputtering rate was 4 nm/min. The resulting thin film exhibited bluish color, indicating inclusion of hydride ions.

### (Determination of Crystal Structure of Thin Film)

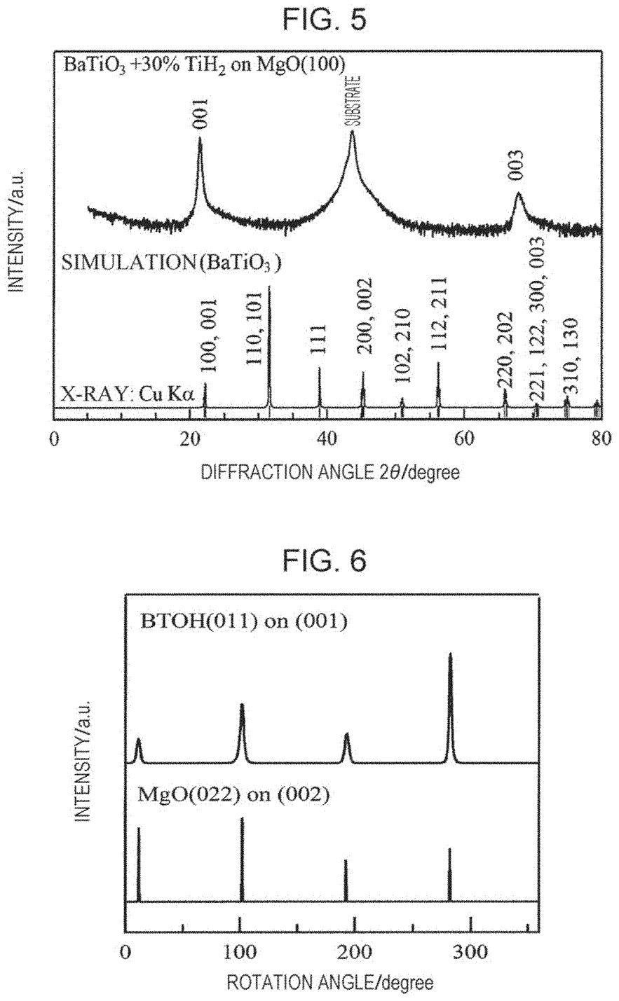

The crystal structure of the thin film of Example 1 was analyzed using an X-ray diffractometer (manufactured by RIGAKU, trade name: RINT-TTR III, ray type: CuKα). An X-ray diffraction profile of the thin film of Example 1 is shown at the top of FIG. 5. Furthermore, regarding a perovskite-type crystal structure having the same composition as that of the material constituting the thin film of Example 1, an X-ray diffraction profile by simulation is shown at the bottom of FIG. 5.

The peak positions in the profile at the top substantially matched with the 00I (I: integer) peak positions in the profile at the bottom. Therefore, it was confirmed that the resulting BTOH thin film had a (001) orientation on the MgO substrate having a (100) plane orientation. Furthermore, as shown in FIG. 6, the diffraction pattern corresponding to the 022 plane of the substrate and the diffraction pattern corresponding to the 011 plane of the thin film had peaks at substantially the same rotation angles. This showed that the thin film was cube-on-cube epitaxially grown. It was confirmed from these evaluations based on X-ray diffraction measurements that the thin film of Example 1 had a perovskite structure. The lattice constants of the crystal structure confirmed from the profiles at the top of FIG. 5 and FIG. 6 were a=0.404 nm and c=0.416 nm. These values are higher than the lattice constants (a=0.399 nm and c=0.409 nm) of BaTiO₃ in general. The reason therefor is assumed to be that the ionic radius of a hydride ion (H⁻: 0.146 nm) is larger than the ionic radius of an oxide ion (O²⁻: 0.140 nm).

### (Determination of Compositional Ratio of Materials Constituting Thin Film)

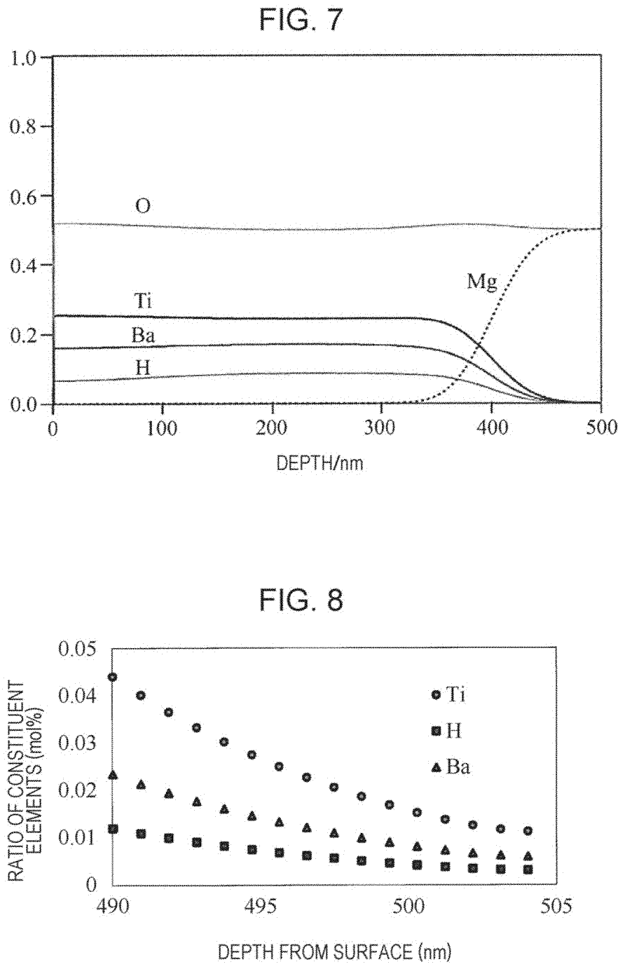

The compositional ratio of materials constituting the thin film of Example 1 was determined by RBS/HFS. FIG. 7 shows the compositional ratio in the depth direction obtained by the measurement. As shown in FIG. 7, although varying in the depth direction of the thin film, the compositional ratio was represented on average by Ba_{0.67}TiO_{2.06}H_{0.32}. As shown in Non-Patent Literature 2, in BTOH, H⁻ is more stable in terms of energy than H⁺. Accordingly, the hydrogen shown in FIG. 7 is considered to correspond to hydride ions.

### (Determination of Hydrogen Content in Substrate)

The hydrogen content in the substrate of Example 1 after the thin film had been formed thereon was determined by a RBS/HFS method. FIG. 8 shows the ratio of constituent elements in the depth direction obtained by the measurement. The unit of measure for the ratio of constituent elements is mol %. The horizontal axis of the graph of FIG. 8 represents the depth from the surface of the thin film. The region located at a depth greater than or equal to 490 nm is a region in the substrate, and is considered to be a region that is sufficiently deep to evaluate the hydrogen content in the substrate. As shown in FIG. 8, the hydrogen content in the substrate was less than or equal to 0.015 mol %.

### (Measurement of Electrical Conductivity)

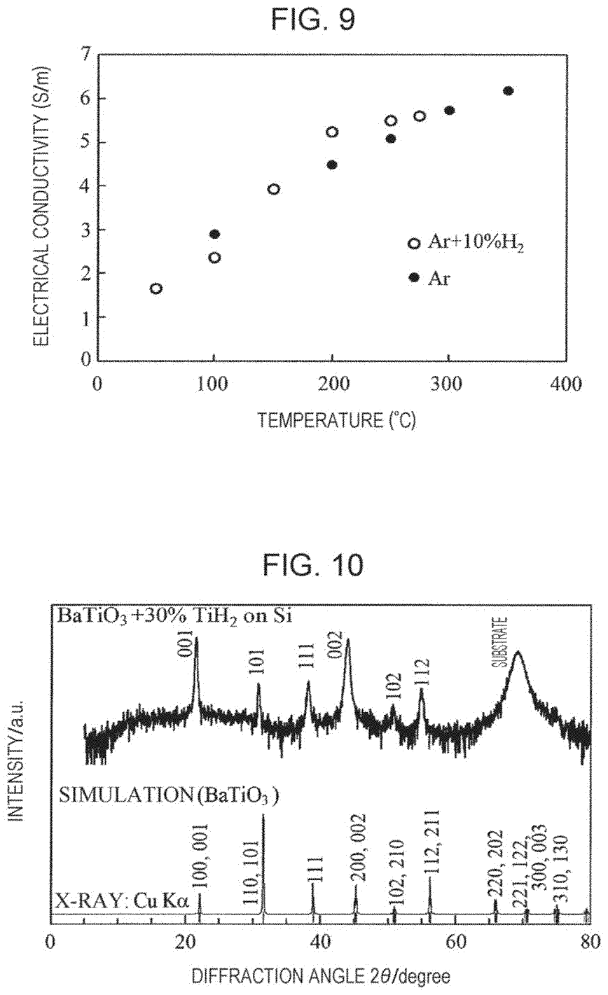

The electrical conductivity of the thin film of Example 1 was measured as electronic and ionic mixed conductivity using an impedance analyzer Celltest System 1470E and MultiStat manufactured by Solatron Analytical Corporation. The measurement atmosphere was set to be a mixed gas atmosphere of argon and hydrogen (hydrogen ratio: 0 to 10% by volume), The pressure in the measurement atmosphere was set to be the atmospheric pressure. The temperature of the measurement atmosphere was set in a range of normal temperature to 350° C. FIG. 9 shows the electrical conductivity of the thin film of Example 1. Unlike the thin film obtained in a mere hydrogen atmosphere as shown in Non-Patent Literature 1, the thin film of Example 1 exhibited high electrical conductivity. The results described above confirmed that the thin film of Example 1 had a crystal structure in which some of oxide ions in BaTiO₃ with a perovskite structure were replaced by hydride ions.

### Example 2

A BTOH thin film was produced as in Example 1 except that an Si substrate having a (100) plane orientation (purchased from Furuuchi Chemical Corporation) was used instead of the MgO substrate having a (100) plane orientation, and the sputtering power was changed to 200 W.

The resulting thin film exhibited bluish color, indicating inclusion of hydride ions.

The crystal structure of the thin film of Example 2 was determined as in Example 1. As shown in FIG. 10, in the thin film of Example 2, various peaks derived from perovskite were confirmed. This means that the thin film of Example 2 has a perovskite structure and is grown as polycrystalline. The lattice constants of the confirmed crystal structure were a, c=0413 nm.

The compositional ratio of materials constituting the thin film of Example 2 was determined as in Example 1. The determined compositional ratio was represented on average by Ba_{0.47}TiO_{2.00}H_{0.41}.

Si and Si substrates are substance and materials, the technology for which has been established, in terms of industrial application. Being possible to form a BTOH thin film on an Si substrate means that by using a processing technique, such as etching, application is possible, for example, to a device in which a BTOH thin film is used as a reaction electrode.

### Example 3

An STOH thin film was produced as in Example 1 except that an SrTiO₃ powder (purchased from Kojundo Chemical Laboratory Co., Ltd., purity: 99.9%) was used instead of the BaTiO₃ powder, an MgO substrate having a (110) plane orientation (purchased from Crystal Base Co., Ltd.) was used instead of the MgO substrate having a (100) plane orientation, the sputtering power was changed to 140 W, and the substrate temperature was changed to 420° C.

The resulting thin film exhibited bluish color, indicating inclusion of hydride ions.

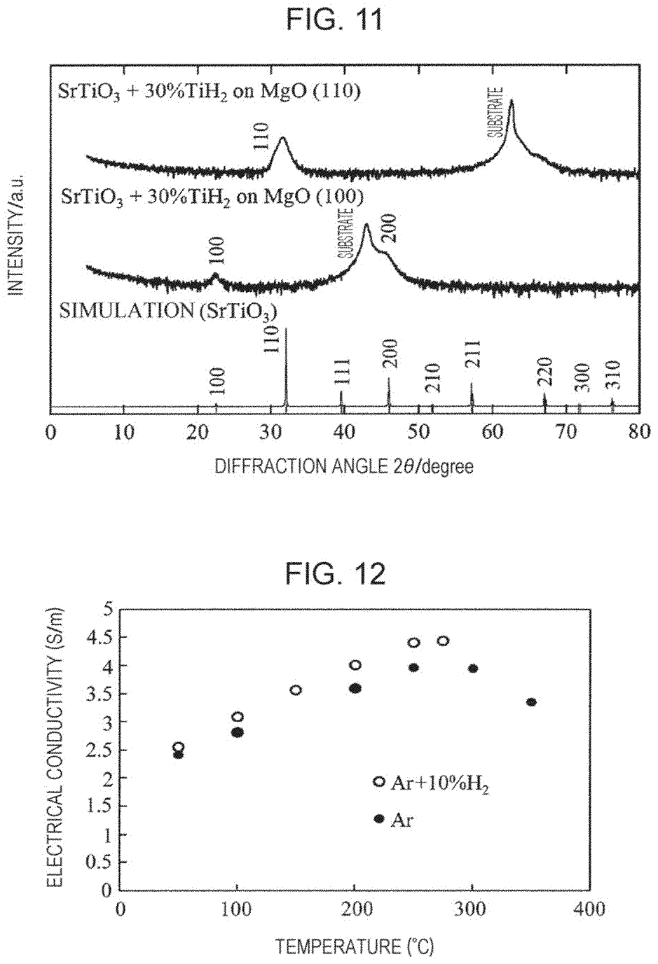

The crystal structure of the thin film of Example 3 was determined as in Example 1. As shown in FIG. 11, in the thin film of Example 3, only the (110) peak derived from perovskite was observed. The lattice constants of the confirmed crystal structure were a, c=0.401 nm,

The compositional ratio of materials constituting the thin film of Example 3 was determined as in Example 1. The determined compositional ratio was represented on average by Sr_{0.67}TiO_{2.90}H_{0.10}.

### Example 4

An STOH thin film was produced as in Example 3 except that an MgO substrate having a (100) plane orientation (purchased from Crystal Base Co., Ltd.) was used instead of the MgO substrate having a (110) plane orientation.

The resulting thin film exhibited bluish color, indicating inclusion of hydride ions.

The crystal structure of the thin film of Example 4 was determined as in Example 1. As shown in FIG. 11, it was confirmed that the thin film of Example 4 had a perovskite structure. The lattice constants of the confirmed crystal structure were a, c=0.396 nm.

The electrical conductivity of the thin film of Example 4 was measured as in Example 1. FIG. 12 shows the electrical conductivity of the thin film of Example 4. Unlike the thin film obtained in a mere hydrogen atmosphere as shown in Non-Patent Literature 1, the thin film of Example 4 exhibited high electrical conductivity.

The compositional ratio of materials constituting the thin film of Example 4 was determined as in Example 1. The determined compositional ratio was represented on average by Sr_{0.80}TiO_{2.49}H_{0.35}.

### Example 5

A BTOH thin film was produced as in Example 1 except that a stainless steel (SUS403) substrate was used instead of the MgO substrate having a (100) plane orientation.

The resulting thin film exhibited bluish color, indicating inclusion of hydride ions.

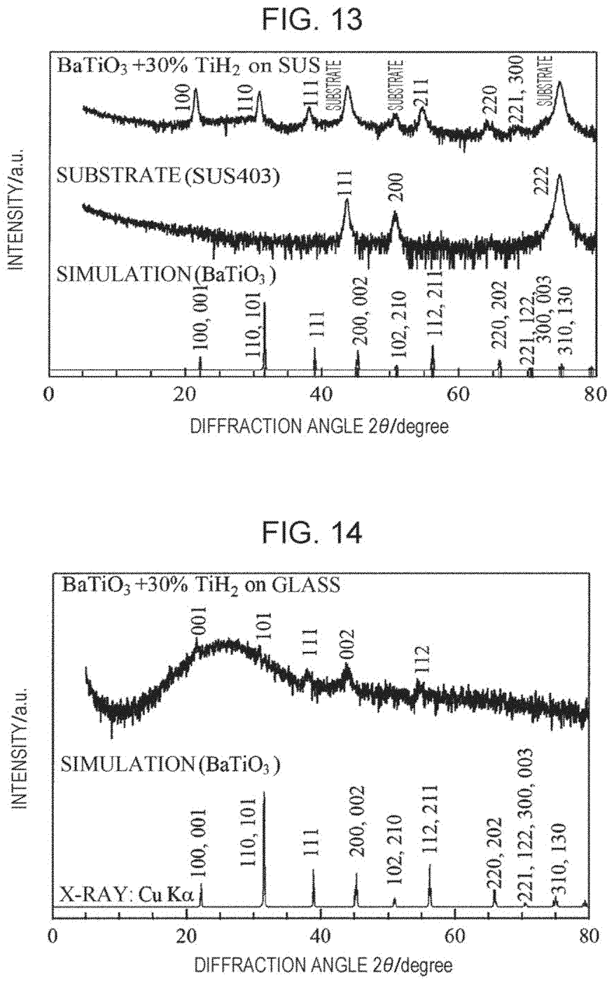

The crystal structure of the thin film of Example 5 was determined as in Example 1. As shown in FIG. 13, in the thin film of Example 5, various peaks derived from perovskite were observed. This means that the thin film of Example 5 has a perovskite structure and is grown as polycrystalline. The lattice constants of the confirmed crystal structure were a, c=0415 nm.

The compositional ratio of materials constituting the thin film of Example 5 was determined as in Example 1. The determined compositional ratio was represented on average by Ba_{0.55}TiO_{2.27}H_{0.44}.

### Example 6

A BTOH thin film was produced as in Example 1 except that a glass substrate was used instead of the MgO substrate having a (100) plane orientation. The glass constituting the glass substrate was borosilicate glass.

The resulting thin film exhibited bluish color, indicating inclusion of hydride ions.

The crystal structure of the thin film of Example 6 was determined as in Example 1. As shown in FIG. 14, in the thin film of Example 6, various peaks derived from perovskite were observed. This means that the thin film of Example 6 has a perovskite structure and is grown as polycrystalline. The lattice constants of the confirmed crystal structure were a, c=0.414 nm.

The compositional ratio of materials constituting the thin film of Example 6 was determined as in Example 1. The determined compositional ratio was represented on average by Ba_{0.60}TiO_{2.14}H_{0.28}.

### Example 7

An STOH thin film was produced as in Example 3 except that an Al₂O₃ substrate having a (001) plane orientation (purchased from Crystal Base Co., Ltd.) was used instead of the MgO substrate having a (110) plane orientation, and the sputtering power was changed to 160 W.

The resulting thin film exhibited bluish color, indicating inclusion of hydride ions.

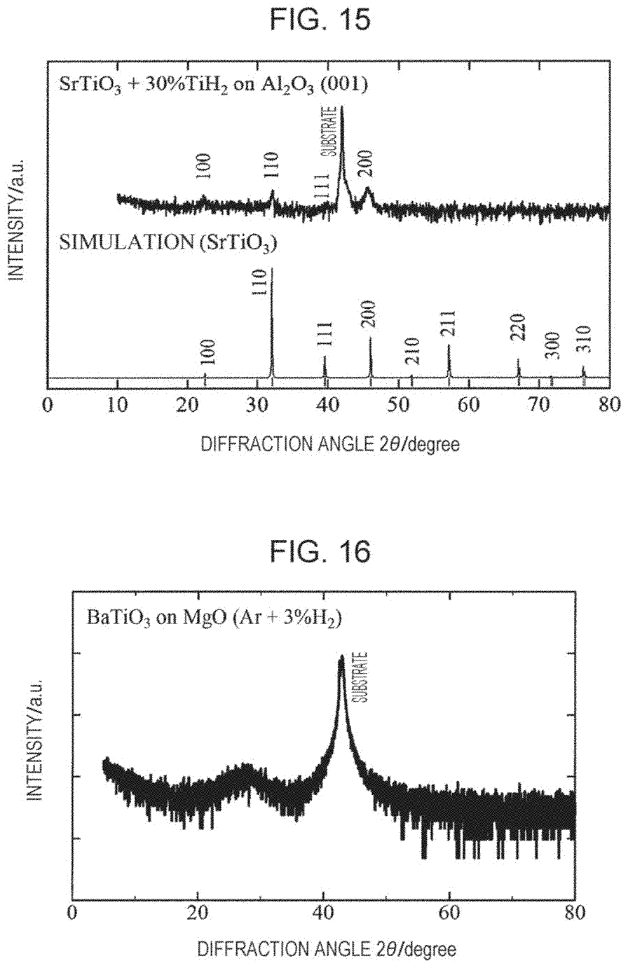

The crystal structure of the thin film of Example 7 was determined as in Example 1. As shown in FIG. 15, in the thin film of Example 7, various peaks derived from perovskite were observed. This means that the thin film of Example 7 has a perovskite structure and is grown as polycrystalline. The lattice constants of the confirmed crystal structure were a, c=0.398 nm.

The compositional ratio of materials constituting the thin film of Example 7 was determined as in Example 1. The determined compositional ratio was represented on average by Sr_{0.66}TiO_{2.27}H_{0.22}.

### Comparative Example 1

A BaTiO₃ thin film was produced as in Example 1 except that a BaTiO₃ powder only was used as the target, and a gas in which 3% by volume of H₂ was added to Ar was used in film formation.

The resulting thin film was colorless and transparent. The electrical conductivity of the resulting thin film was measured as in Example 1. However, the thin film did not exhibit electrical conductivity.

The crystal structure of the thin film of Comparative Example 1 was determined as in Example 1. As shown in FIG. 16, the thin film was amorphous and had no crystal growth.

### Comparative Example 2

A thin film was produced as in Example 1 except that a mixture of a BaTiO₃ powder and a Ba(OH)₂ powder was used as the target. The mixing ratio of the BaTiO₃ powder and the Ba(OH)₂ powder, in terms of weight ratio, was 10:1.

The resulting thin film was colorless and transparent and was unstable in the air. The electrical conductivity of the resulting thin film was measured as in Example 1. However, the thin film did not exhibit electrical conductivity.

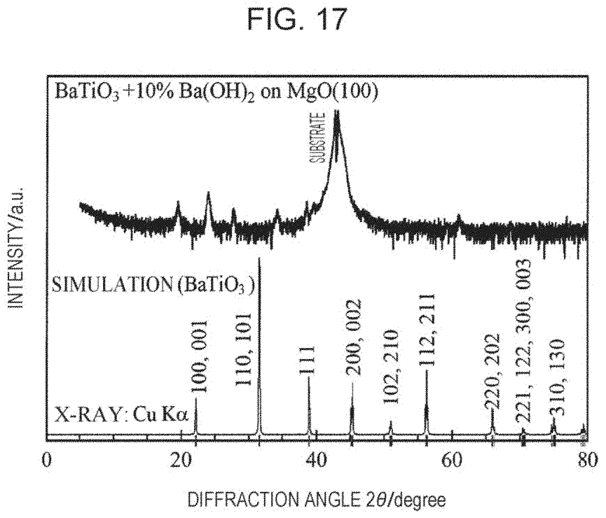

The crystal structure of the thin film of Comparative Example 2 was determined as in Example 1. As shown in FIG. 17, diffraction peaks were present at positions different from those of either BTOH or BaTiO₃. Thus, it was confirmed that the thin film of Comparative Example 2 was not either a BTOH thin film or a BaTiO₃ thin film. It was also confirmed that even when protic hydrogen was used as a raw material, a BTOH thin film failed to be produced.

According to the method of the present disclosure, it is possible to produce a thin film of a titanium-containing oxide containing hydride ions. The produced thin film can be utilized, for example, for a material for chemical conversion, a catalyst, or an electrode, each of which adds hydrogen to organic substance.

What is claimed is:

1. A method for producing a thin film, the method comprising:
forming the thin film on a substrate using a target,
wherein the target is formed of a mixture containing a first material and a second material,
the first material has a composition represented by ATiO₃ (where A is at least one selected from the group consisting of Ba and Sr),
the second material has a composition represented by EH₂ (where E is at least one selected from the group consisting of Ti and Zr),
the thin film is formed of a first oxide containing A, Ti, and O, and
some of oxide ions contained in the first oxide have been replaced by hydride ions.

2. The method according to claim 1, wherein the first oxide has a crystal structure.

3. The method according to claim 2, wherein the crystal structure is a perovskite structure.

4. The method according to claim 1, wherein the first oxide has a composition represented by AₓTiO_{3-y}H_{z} (0.4≤x≤0.8, 0.1≤y≤1.0, 0.1≤z≤1.0).

5. The method according to claim 1, wherein the substrate is formed of at least one selected from the group consisting of Si, Ge, a metal, an amorphous substance, and a metal compound that is different from the first oxide.

6. The method according to claim 5, wherein the metal is stainless steel.

7. The method according to claim 5, wherein the amorphous substance is glass.

8. The method according to claim 5, wherein the metal compound has a higher oxidation-reduction potential than a hydride ion.

9. The method according to claim 5, wherein the metal compound is at least one selected from the group consisting of Al₂O₃, SnO, GaAs, and GaN.

10. The method according to claim 5, wherein the metal compound is a substance which has been doped with hydrogen by heat treatment using a reducing agent composed of a hydride.

11. The method according to claim 5, wherein the metal compound is at least one selected from the group consisting of MgO and BaSnO₃.

12. The method according to claim 1, wherein the substrate is formed of Si having a (100) plane orientation.

13. The method according to claim 1, wherein the substrate is formed of MgO having a (100) or (110) plane orientation.

14. The method according to claim 13, wherein the thin film is epitaxially grown on the substrate.

15. The method according to claim 1, wherein the first material has a composition represented by BaTiO₃, and a mixing ratio (X:Y) of the first material (X) and the second material (Y) in the mixture, in terms of molar ratio, is in a range of 1:0.01 to 1:1.

16. The method according to claim 1, wherein the first material has a composition represented by SrTiO₃, and a mixing ratio (X:Y) of the first material (X) and the second material (Y) in the mixture, in terms of molar ratio, is in a range of 1:0.01 to 2:1.

17. The method according to claim 1, wherein the thin film is formed on the substrate by a sputtering method.

18. A multilayer body comprising:
a substrate; and
a thin film formed on the substrate,
wherein the thin film is formed of a first oxide containing A, Ti, and O,
where A is at least one selected from the group consisting of Ba and Sr,
some of oxide ions contained in the first oxide have been replaced by hydride ions,
the substrate is formed of at least one selected from the group consisting of Si, Ge, and a metal compound that is different from the first oxide, and
the metal compound is a substance
(a) which has a higher oxidation-reduction potential than hydride ion, or
(b) which is doped with hydrogen by heat treatment using a reducing agent composed of a hydride.

19. The multilayer body according to claim 18, wherein the substrate is formed of at least one selected from the group consisting of Si and Ge.

20. The multilayer body according to claim 18, wherein the metal compound is at least one selected from the group consisting of Al₂O₃, SnO, GaAs, GaN, MgO, and BaSnO₃.

21. A multilayer body comprising:
a substrate; and
a thin film formed on the substrate,
wherein the thin film is formed of a first oxide containing A, Ti, and O,
where A is at least one selected from the group consisting of Ba and Sr,
some of oxide ions contained in the first oxide have been replaced by hydride ions, and
a hydrogen content in the substrate is less than or equal to 0.05 mol %.

22. The multilayer body according to claim 21, wherein the substrate is formed of at least one selected from the group consisting of Si and Ge.

23. The multilayer body according to claim 18, wherein the first oxide has a crystal structure.

24. The multilayer body according to claim 23, wherein the crystal structure is a perovskite structure.

25. The multilayer body according to claim 18, wherein the first oxide has a composition represented by AₓTiO_{3-y}H_{z} (0.4≤x≤0.8, 0.1≤y≤1.0, 0.1≤z≤1.0).
